(19) United States
(12) Patent Application Publication
(10) Pub. No.: US 2025/0342285 A1
(43) Pub. Date: Nov. 6, 2025

(54) SYSTEM AND METHOD FOR COMPUTING RELATIVE CONFIDENCE OF SEISMIC INTERPRETATION

(71) Applicant: Schlumberger Technology Corporation, Sugar Land, TX (US)

(72) Inventors: Shaan Dhumale, London (GB); Matthew Ellwood, Oxford (GB); Martin Haege, Calgary (CA)

(21) Appl. No.: 19/199,907

(22) Filed: May 6, 2025

Related U.S. Application Data
(60) Provisional application No. 63/642,998, filed on May 6, 2024.

(51) Int. Cl. G06F 30/10

(52) U.S. Cl. CPC G06F 30/10

(57) ABSTRACT

A system and method in accordance with the present disclosure include a workflow applied to identify areas of confidence in seismic interpretations that meets a pre-selected threshold by utilizing machine-learning (ML) techniques. The ML techniques enable one or more filters to be applied, based on a range of confidence values, to areas of seismic interpretation both in the vicinity of the faults but also away from fault locations. The contribution of the various inputs is evaluated and weighted by the ML model, which reduces the time to prepare input seismic interpretation data and to obtain results from executing the model.

### CROSS-REFERENCE TO RELATED APPLICATIONS

This patent application claims priority to U.S. Provisional Patent Application No. 63/642,998, filed on May 6, 2024, which is incorporated by reference herein in its entirety.

### BACKGROUND

Seismic interpretation forms an input into the process of constructing a 3D subsurface model. The nature of interpretation renders seismic interpretation uncertain at times. Relative confidence in seismic interpretation helps in constructing a 3D subsurface framework. Identifying confidence in areas of interpretation can enable effective filtering or weighting when constructing a representation of the model. Typically, low confidence data are identified and filtered using a static filter in the proximity of fault locations, considering that seismic image quality is often deteriorated in the vicinity of faults. Static filtering can be conducted by applying coarse and static operators to the seismic interpretation. For example, performing a filtering of data within a set proximity to fault locations can reduce the likelihood of generating modelling related artefacts. Filtering in this way can be indiscriminate, often undesirably filtering high confidence and valuable information used to produce a robust and accurate subsurface framework.

Seismic interpretation may have a relatively low confidence measure because, for example, the data lack conformance to the seismic/attribute volume in which the data were interpreted from, or when the seismic/attribute volume suffers from poor fault imaging quality, or more generally where seismic resolution is unable to effectively resolve a geological event of interest leading to increased uncertainty in the interpretation.

### SUMMARY

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a non-transitory computer-readable medium storing instructions for computing a relative confidence of one or more seismic interpretation objects that, when executed by one or more processors of a computing system, cause the computing system to perform operations. The operations include (a) receiving the one or more seismic interpretation objects associated with a subsurface area.

The operations also include (b) computing one or more geometric or seismic attribute volumes and descriptor volumes associated with the one or more seismic interpretation objects. The one or more geometric or seismic attribute volumes and the descriptor volumes include coordinates including x, y, and depth, edges, surface stability, vector attributes, horizon and fault prediction, seismic amplitude, surface attributes, seismic signature, horizon discontinuities, fault surfaces dominant frequency, reflectional intensity, and gradient magnitude.

The operations include (c) processing the one or more seismic interpretation objects and the one or more geometric or seismic attribute volumes and the descriptor volumes to form an analysis dataset. The processing includes labeling the one or more seismic interpretation objects and the one or more geometric or seismic attribute volumes and the descriptor volumes based on characteristics of the one or more seismic interpretation objects and the one or more geometric or seismic attribute volumes and the descriptor volumes. The characteristics include data quality, data geographic location, and proximity to a seismic feature. The processing includes removing nulls and duplicates from the labeled one or more seismic interpretation objects and the labeled one or more geometric or seismic attribute volumes and the descriptor volumes to produce cleaned data. The processing includes scaling the cleaned data to produce scaled data, balancing the scaled data to produce balanced data, and merging the balanced data to produce the analysis dataset. The analysis dataset includes the labeled one or more seismic interpretation objects.

The operations also include (d) iteratively training a machine learning (ML) model based on the analysis dataset, and weighting and evaluating the one or more geometric or seismic attribute volumes and the descriptor volumes resulting in a probability prediction value for each coordinate in the subsurface area. The probability prediction value includes a continuous representation of the relative confidence in the one or more seismic interpretation objects. The continuous representation is tested against a set of metrics to determine if the ML model is to be adjusted to improve model performance.

The operations include (e) predicting the relative confidence in a second set of the one or more seismic interpretation objects by providing a processed second set of the one or more seismic interpretation objects and a second set of the one or more geometric or seismic attribute volumes and the descriptor volumes to the trained ML model, and computing the relative confidence in the processed second set of the one or more seismic interpretation objects based on the probability prediction value from the trained ML model. The predicting includes receiving and processing the second set of the one or more seismic interpretation objects and a second set of the one or more geometric or seismic attribute volumes and the descriptor volumes according to blocks (a)-(c), providing the processed second set of the one or more seismic interpretation objects and the second set of the one or more geometric or seismic attribute volumes and the descriptor volumes to the trained ML model, and computing the relative confidence in the second set of the one or more seismic interpretation objects based on the probability prediction value from the trained ML model.

The operations also include (f) updating a 3D subsurface framework based on the computed relative confidence to improve subsurface framework quality and field development decisions related to the 3D subsurface framework, displaying the updated 3D subsurface framework, and performing a wellsite action. Other embodiments of this aspect include corresponding computer systems, apparatus, and computer programs recorded on one or more computer storage devices, each configured to perform the actions of the methods.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates an example of a system that includes various management components to manage various aspects of a geologic environment, according to an embodiment.

FIG. 2 is a flowchart illustrating a method in accordance with embodiments of the present disclosure operable to compute relative confidence of seismic interpretation.

FIGS. 3A and 3B are images of seismic and geometric attributes.

FIGS. 4A and 4B are images of target labelling classification. Data courtesy of Geoscience Australia.

FIGS. 5A and 5B are images displaying probability values from seismic versus geometric attribute-based models.

FIGS. 6A-6C are images of seismic data filtering.

FIGS. 7A and 7B are images of filtered seismic data using static filter and ML filtering, respectively.

FIG. 8 illustrates a schematic view of a computing system, in accordance with embodiments of the present disclosure.

### DETAILED DESCRIPTION

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits, and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques, and workflows that are in accordance with some embodiments. Some operations in the processing procedures, methods, techniques, and workflows disclosed herein may be combined and/or the order of some operations may be changed.

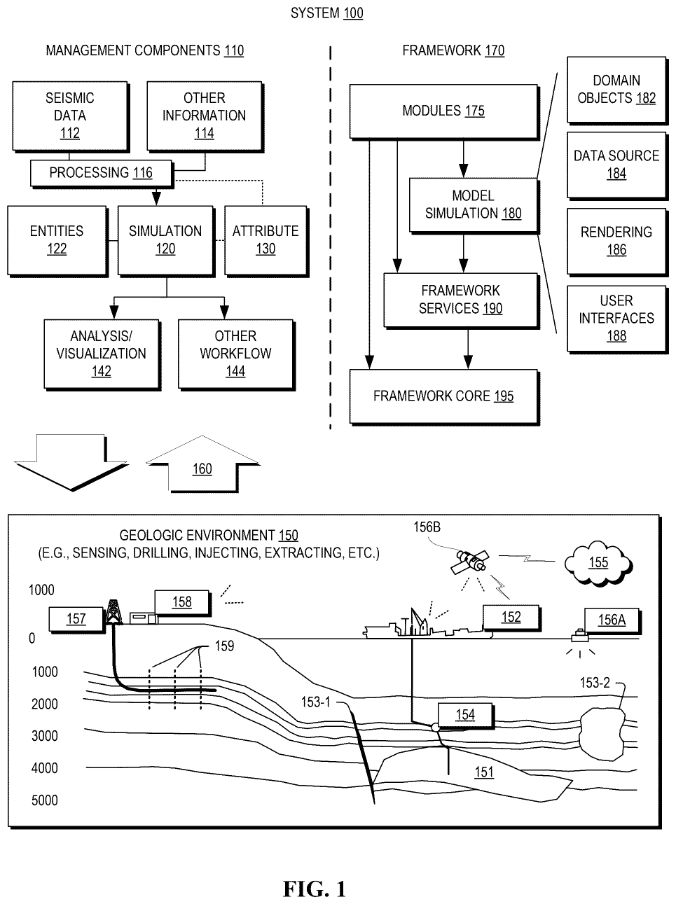

FIG. 1 illustrates an example of a system 100 that includes various management components 110 to manage various aspects of a geologic environment 150 (e.g., an environment that includes a sedimentary basin, a reservoir 151, one or more faults 153-1, one or more geobodies 153-2, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data), a processing component 116, a simulation component 120, an attribute component 130, an analysis/visualization component 142 and a workflow component 144. In operation, seismic data and other information provided per the components 112 and 114 may be input to the simulation component 120.

In an example embodiment, the simulation component 120 may rely on entities 122. Entities 122 may include earth entities or geological objects such as wells, surfaces, bodies, reservoirs, etc. In the system 100, the entities 122 can include virtual representations of actual physical entities that are reconstructed for purposes of simulation. The entities 122 may include entities based on data acquired via sensing, observation, etc. (e.g., the seismic data 112 and other information 114). An entity may be characterized by one or more properties (e.g., a geometrical pillar grid entity of an earth model may be characterized by a porosity property). Such properties may represent one or more measurements (e.g., acquired data), calculations, etc.

In an example embodiment, the simulation component 120 may operate in conjunction with a software framework such as an object-based framework. In such a framework, entities may include entities based on pre-defined classes to facilitate modeling and simulation. A commercially available example of an object-based framework is the MICROSOFT® .NET® framework (Redmond, Washington), which provides a set of extensible object classes. In the .NET® framework, an object class encapsulates a module of reusable code and associated data structures. Object classes can be used to instantiate object instances for use in by a program, script, etc. For example, borehole classes may define objects for representing boreholes based on well data.

In the example of FIG. 1, the simulation component 120 may process information to conform to one or more attributes specified by the attribute component 130, which may include a library of attributes. Such processing may occur prior to input to the simulation component 120 (e.g., consider the processing component 116). As an example, the simulation component 120 may perform operations on input information based on one or more attributes specified by the attribute component 130. In an example embodiment, the simulation component 120 may construct one or more models of the geologic environment 150, which may be relied on to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as the ECLIPSE™ reservoir simulator (Schlumberger Limited, Houston Texas), the INTERSECT™ reservoir simulator (Schlumberger Limited, Houston Texas), etc. As an example, a simulation component, a simulator, etc. may include features to implement one or more meshless techniques (e.g., to solve one or more equations, etc.). As an example, a reservoir or reservoirs may be simulated with respect to one or more enhanced recovery techniques (e.g., consider a thermal process such as SAGD, etc.).

In an example embodiment, the management components 110 may include features of a commercially available framework such as the PETREL® seismic to simulation software framework (Schlumberger Limited, Houston, Texas). The PETREL® framework provides components that allow for optimization of exploration and development operations. The PETREL® framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes. Such a framework may be considered an application and may be considered a data-driven application (e.g., where data is input for purposes of modeling, simulating, etc.).

In an example embodiment, various aspects of the management components 110 may include add-ons or plug-ins that operate according to specifications of a framework environment. For example, a commercially available framework environment marketed as the OCEAN® framework environment (Schlumberger Limited, Houston, Texas) allows for integration of add-ons (or plug-ins) into a PETREL® framework workflow. The OCEAN® framework environment leverages.NET® tools (Microsoft Corporation, Redmond, Washington) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may include the commercially available OCEAN® framework where the model simulation layer 180 is the commercially available PETREL® model-centric software package that hosts OCEAN® framework applications. In an example embodiment, the PETREL® software may be considered a data-driven application. The PETREL® software can include a framework for model building and visualization.

As an example, a framework may include features for implementing one or more mesh generation techniques. For example, a framework may include an input component for receipt of information from interpretation of seismic data, one or more attributes based at least in part on seismic data, log data, image data, etc. Such a framework may include a mesh generation component that processes input information, optionally in conjunction with other information, to generate a mesh.

In the example of FIG. 1, the model simulation layer 180 may provide domain objects 182, act as a data source 184, provide for rendering 186 and provide for various user interfaces 188. Rendering 186 may provide a graphical environment in which applications can display their data while the user interfaces 188 may provide a common look and feel for application user interface components.

As an example, the domain objects 182 can include entity objects, property objects and optionally other objects. Entity objects may be used to geometrically represent wells, surfaces, bodies, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results and cases. Thus, upon completion of a modeling session, a user may store a project. At a later time, the project can be accessed and restored using the model simulation layer 180, which can recreate instances of the relevant domain objects.

In the example of FIG. 1, the geologic environment 150 may include layers (e.g., stratification) that include a reservoir 151 and one or more other features such as the fault 153-1, the geobody 153-2, etc. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or instead include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL® software, for example, that operates on seismic data, seismic attribute(s), etc. As an example, a workflow may be a process implementable in the OCEAN® framework. As an example, a workflow may include one or more worksteps that access a module such as a plug-in (e.g., external executable code, etc.).

Embodiments in accordance with the present disclosure relate to a workflow applied to identify areas of confidence in seismic interpretations that meets a pre-selected threshold by utilizing machine learning (ML) techniques. Systems and methods in accordance with embodiments of the present disclosure address limitations experienced by domain scientists through firstly automating the identification of one confidence level versus another in interpretation, and secondly through enabling a localized approach to seismic interpretation filtering. The ML technique enables one or more filters to be applied, based on a range of confidence values, to areas of seismic interpretation both in the vicinity of the faults but also away from fault locations, in an intelligent manner through analyzing geometrical and signal-based seismic attributes from multiple sources of input. The contribution of the various inputs is evaluated and weighted by the ML model. This significantly reduces the time to prepare input seismic interpretation data and to obtain results from executing the model. In addition, a localized and discriminate approach of filtering is applied which contributes to improving the accuracy of the resulting model.

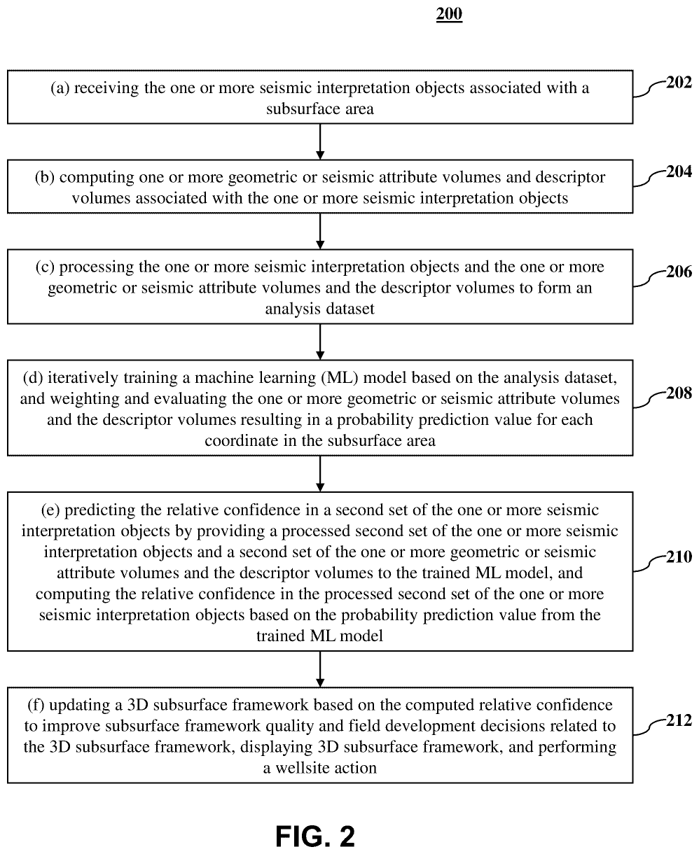

Referring now to FIG. 2, in some configurations, a workflow in accordance with embodiments of the present disclosure is characterized by two main phases: a data preparation and training phase, and a prediction phase. Other phases are contemplated by the present disclosure. In some configurations, the data preparation and training phase can include, but is not limited to including, attribute generation, target class labelling, data cleaning, data scaling, data balancing, data merging and data training of a ML model. The prediction phase is when the trained ML model is applied to unlabeled datasets to predict interpretation confidence. An embodiment in accordance with the present disclosure is illustrated in method 200. Method 200 for computing relative confidence of one or more seismic interpretation objects can include, but is not limited to including, (a) receiving 202 one or more seismic interpretation objects associated with a subsurface area, (b) computing 204 one or more geometric and/or seismic attribute/descriptor volumes associated with the one or more seismic interpretation objects, (c) processing 206 the one or more seismic interpretation objects and the one or more geometric and/or seismic attribute/descriptor volumes to form an analysis dataset, (d) iteratively training 208 a ML model based on the analysis dataset, and weighting and evaluating one or more geometric and/or seismic attribute/descriptor volumes resulting in a probability prediction value for the coordinates in the subsurface area, and repeating block (d) if the ML model is to be adjusted, (e) predicting 210 the relative confidence in a second set of one or more seismic interpretation objects by providing the processed second set of one or more seismic interpretation objects and the second set of one or more geometric and/or seismic attribute/descriptor volumes to the trained ML model, and computing the relative confidence in the second set of one or more seismic interpretation objects based on the probability prediction value from the trained ML model. The method 200 may also include updating the 3D subsurface framework based on the computed relative seismic confidence results for the purpose of improving subsurface framework quality and subsequent field development decisions that are informed fully, or in part, by the 3D subsurface framework. This includes, for example, performing a wellsite action, as at block 212. The wellsite action may be based upon block 210 and/or the combination of any of blocks 202-210. The wellsite action may be or include generating and/or transmitting a signal (e.g., using a computing system) that causes a physical action to occur at a wellsite. The wellsite action may also or instead include performing the physical action at the wellsite. The physical action may include selecting where to drill a wellbore, drilling the wellbore, varying a weight and/or torque on a drill bit that is drilling the wellbore, varying a drilling trajectory of the wellbore, varying a concentration and/or flow rate of a fluid pumped into the wellbore, displaying the output of the physical action, or the like.

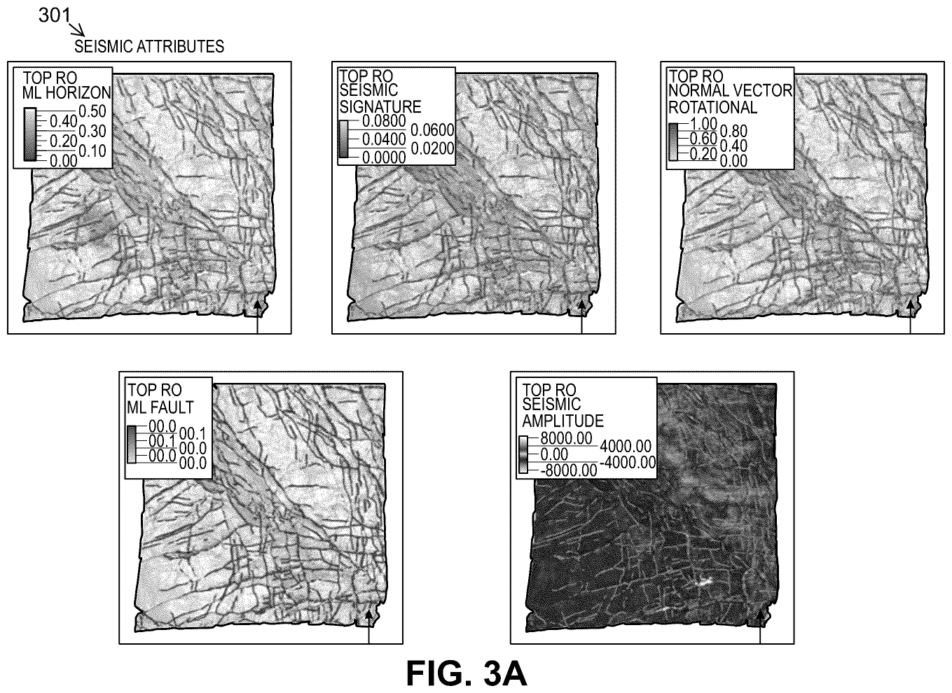

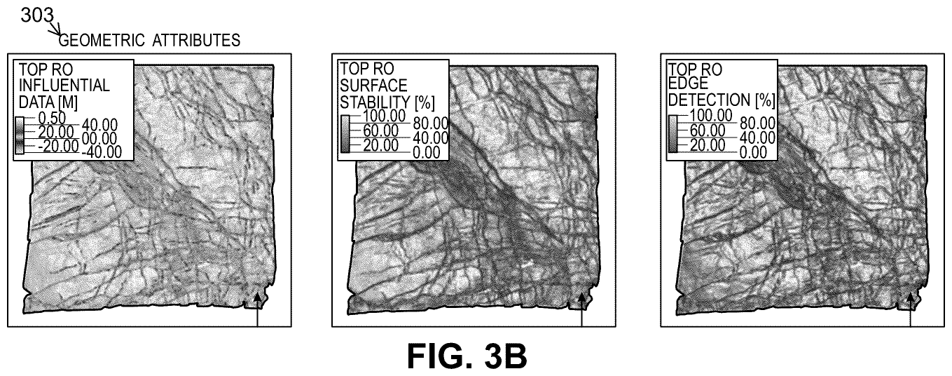

Referring now to FIGS. 3A and 3B, with respect to attribute generation that happens during the first phase, a series of seismic attribute cubes 301 and geometric attribute cubes 303 are computed to be used for training the ML model. The attributes forming the attribute cubes can include, but are not limited to including, coordinates including X, Y, and depth, edges, surface stability, vector attributes, horizon and fault prediction, seismic amplitude, surface attributes, seismic signature, horizon discontinuities, fault surfaces dominant frequency, reflectional intensity, and gradient magnitude. In some configurations, ML horizon and fault probabilities are provided to the ML model to enrich the training.

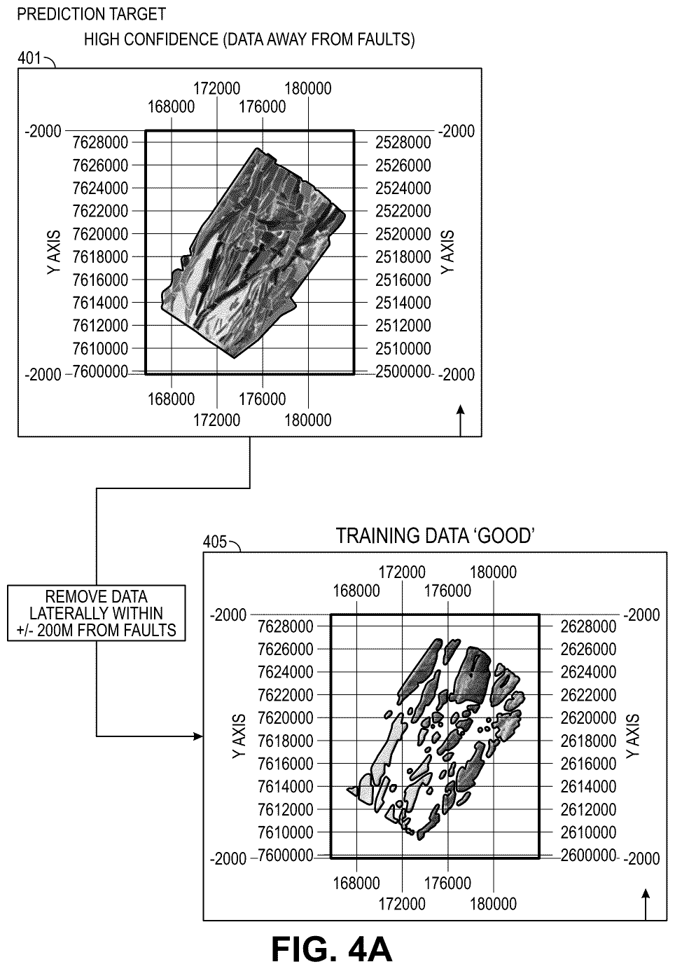

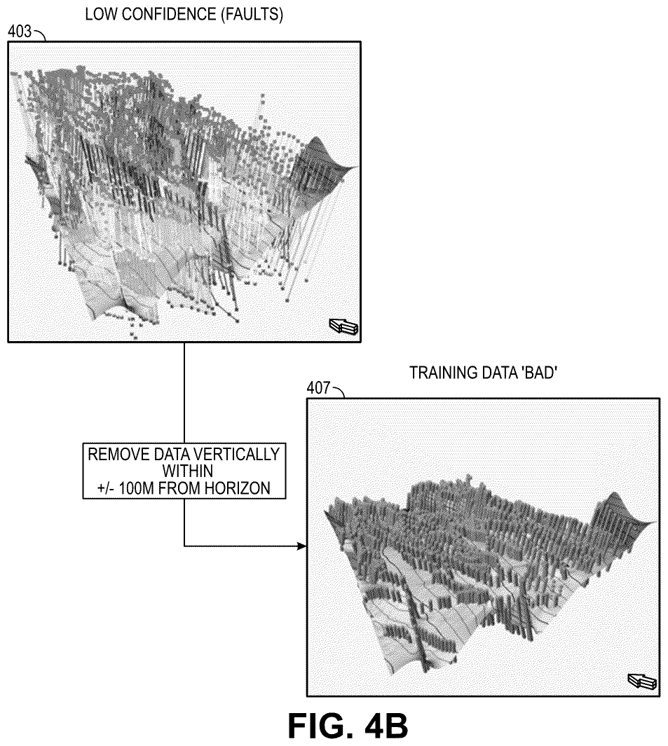

Referring now to FIGS. 4A and 4B, with respect to target class labeling that happens during the first phase, in some configurations, high confidence data 401 and low confidence data 403 can be classified based on a proximity-threshold to faults. Labelled data, high or low confidence, for example, are used as a target class. With respect to confidence prediction in horizon interpretation objects, in some configurations, high confidence data can be classified as data further than 200 m from a fault location. In some configurations, high confidence training data 405 can be prepared by removing data that falls within +/−200 m from faults (laterally, FIG. 4A). In some configurations, low confidence data 403 can be classified as data situated within a 100 m window along a fault plane. In some configurations, low confidence training data 407 can be prepared by removing data that falls within +/−100 m from the horizon (vertically, FIG. 4B). Other characterizations of data are possible.

The first phase of data preparation can include, but is not limited to, data cleaning, data scaling, balancing, and merging. In some configurations, data cleaning is the removal of any null or duplicate data points from attributes and coordinates of interpretation. In some configurations, data scaling is scaling of horizon datasets to ensure that features and attributes are weighted to mitigate the effects of outliers. In some configurations, data balancing is balancing the data to enable the model to predict a minority class. Data balancing can include utilizing, for example, but not limited to, a synthetic minority oversampling technique after scaling so that the model does not become biased towards a majority class. In some configurations, data merging can merge cleaned, scaled, and balanced seismic horizon interpretations and attribute data for training, creating a dataset for analysis.

In some configurations, data training that happens during the first phase includes, but is not limited to including, applying one of various ML algorithms to the data. In some configurations, the random forest algorithm, for example, predicts a target variable (good versus bad predictions of confidence in seismic interpretation objects) based on a series of metrics. The metrics provide insights into the model's ability to predict the target variable based on the input attributes. If the model is found not to be predicting well based on the metrics, data training presents an opportunity to recognize issues with the prediction and adjust the inputs or model parameterization.

In some configurations, the second phase, the data prediction phase includes, but is not limited to including, making predictions, using previously unseen input data, of the confidence level in the target variable (for example, seismic interpretation objects) after the ML model is reliably predicting the target variable. To apply the ML model to previously unseen data, the new data are pre-processed in the same way that the training data were processed, as described herein. The pre-processed data are provided to the trained ML model, and confidence predictions are made by the ML model. The resulting seismic interpretation objects are associated with new continuous probability attributes. Depending on the dataset character, a domain scientist may choose to use the probability attribute from seismic, geometric or a blend of the models to cater to the specific dataset/environment.

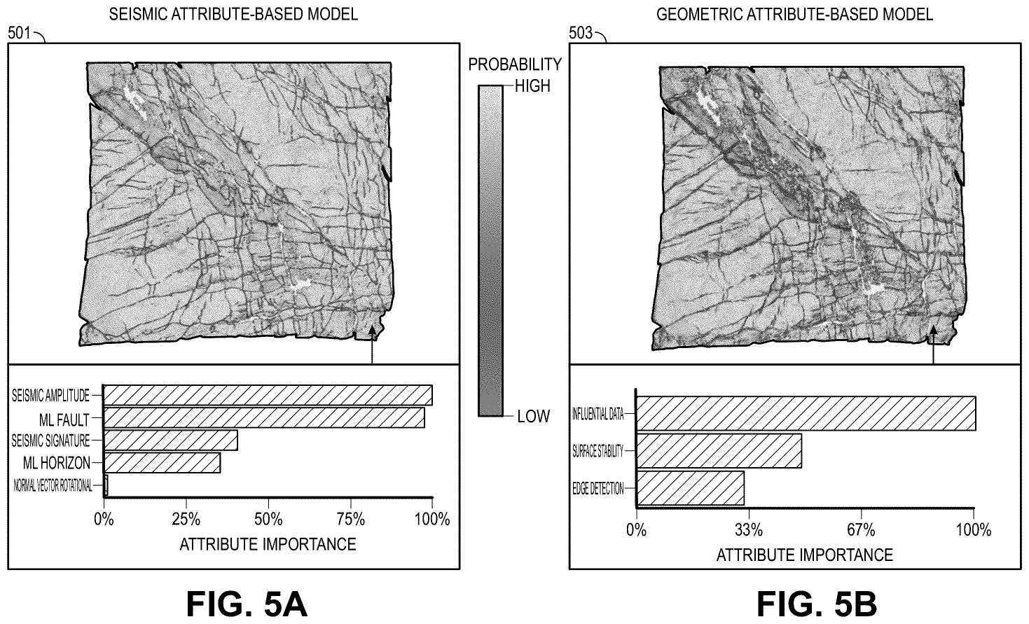

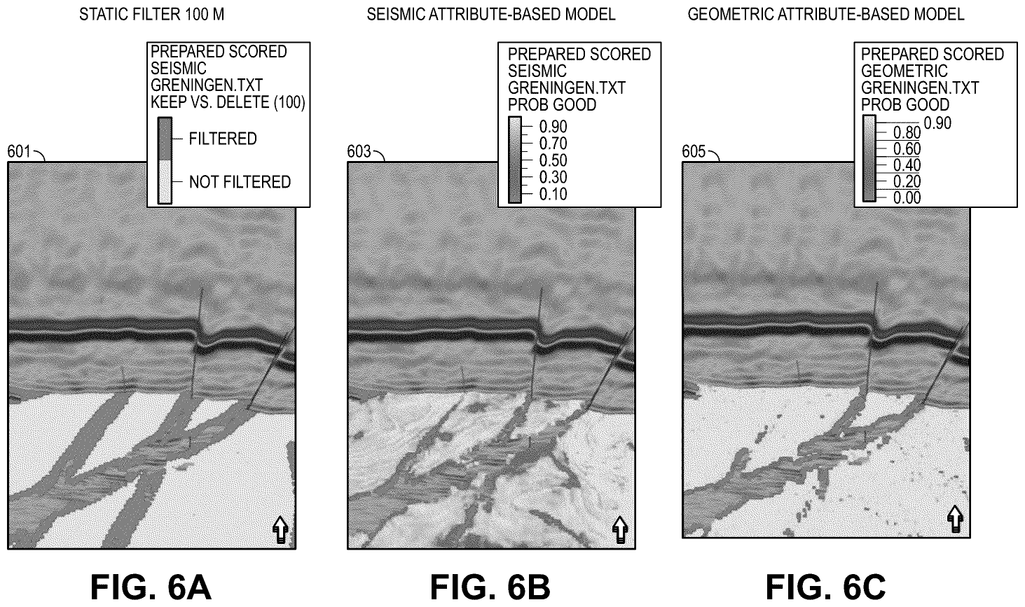

Referring now to FIGS. 5A, 5B and 6A-6C, both seismic attribute-based model results 501 (FIG. 5A) and 603 (FIG. 6B) and geometric-based model results 503 (FIG. 5B) and 605 (FIG. 6C) produce more selective and localized filtering than when static filtering 601 (FIG. 6A) is used. Consequently, information close to fault locations can be consumed into the modelling process. Attribute importance is computed as part of the analysis and can be indicative of the relative influence of the training features.

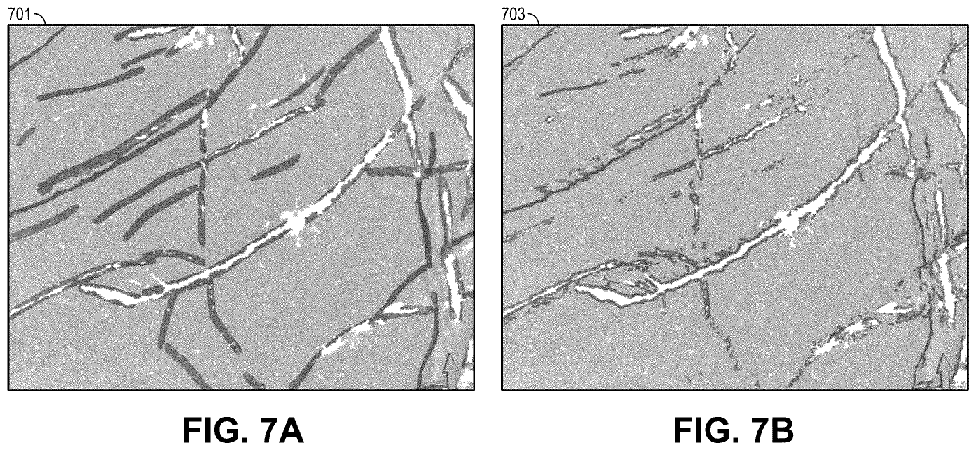

Referring now to FIGS. 7A and 7B, filtered seismic data using static filter and ML filtering, respectively are shown. In the images, the dark gray lines are filtered points and the light gray areas are preserved points. Use of a static distance-based filter is shown in image 701 (FIG. 7A), while use of an ML filtering technique is shown in image 703 (FIG. 7B).

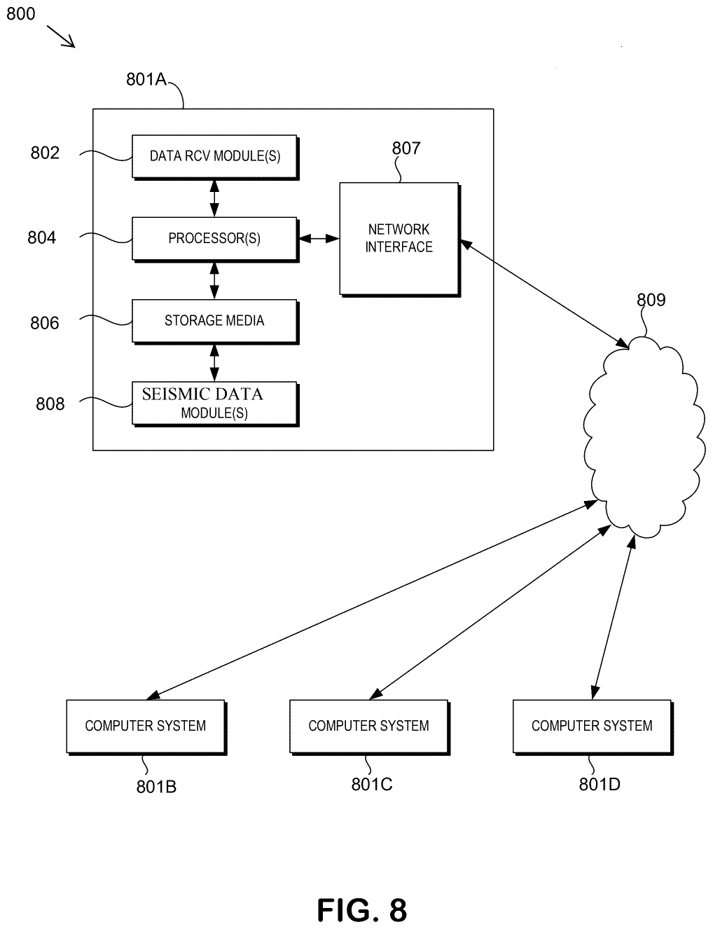

In some embodiments, the methods of the present disclosure may be executed by a computing system. FIG. 8 illustrates an example of such a computing system 800, in accordance with some embodiments. The computing system 800 may include a computer or computer system 801A, which may be an individual computer system 801A or an arrangement of distributed computer systems. The computer system 801A includes one or more data reception and processing modules 802 that are configured to perform various tasks according to some embodiments, such as one or more methods disclosed herein. To perform these various tasks, the data reception and processing module 802 executes independently, or in coordination with, one or more processors 804, which is (or are) connected to one or more storage media 806. The processor(s) 804 is (or are) also connected to a network interface 807 to allow the computer system 801A to communicate over a data network 809 with one or more additional computer systems and/or computing systems, such as 801B, 801C, and/or 801D (note that computer systems 801B, 801C and/or 801D may or may not share the same architecture as computer system 801A, and may be located in different physical locations, e.g., computer systems 801A and 801B may be located in a processing facility, while in communication with one or more computer systems such as 801C and/or 801D that are located in one or more data centers, and/or located in varying countries on different continents).

A processor may include a microprocessor, microcontroller, processor module or subsystem, programmable integrated circuit, programmable gate array, or another control or computing device.

The storage media 806 may be implemented as one or more computer-readable or machine-readable storage media. Note that while in the example embodiment of FIG. 8 storage media 806 is depicted as within computer system 801A, in some embodiments, storage media 806 may be distributed within and/or across multiple internal and/or external enclosures of computing system 801A and/or additional computing systems. Storage media 806 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some embodiments, computing system 800 contains one or more seismic data module(s) 808. In the example of computing system 800, computer system 801A includes the seismic data module 808. In some embodiments, a single subsurface operations module may be used to perform some aspects of one or more embodiments of the methods disclosed herein. In other embodiments, a plurality of subsurface operations modules may be used to perform some aspects of methods herein.

It should be appreciated that computing system 800 is merely one example of a computing system, and that computing system 800 may have more or fewer components than shown, may combine additional components not depicted in the example embodiment of FIG. 8, and/or computing system 800 may have a different configuration or arrangement of the components depicted in FIG. 8. The various components shown in FIG. 8 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 800, FIG. 8), and/or through manual control by a user who may make determinations regarding whether a given step, action, template, model, or set of curves has become sufficiently accurate for the evaluation of the subsurface three-dimensional geologic formation under consideration.

The foregoing description, for purposes of explanation, has been described with reference to specific embodiments. However, the illustrative discussions above are not intended to be exhaustive or limiting to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principles of the disclosure and its practical applications, to thereby enable others skilled in the art to best utilize the disclosed embodiments and various embodiments with various modifications as are suited to the particular use contemplated.

1. A method for predicting a relative confidence of one or more seismic interpretation objects, the method comprising:
(a) receiving the one or more seismic interpretation objects associated with a subsurface area;
(b) computing one or more geometric or seismic attribute volumes and descriptor volumes associated with the one or more seismic interpretation objects;
(c) processing the one or more seismic interpretation objects and the one or more geometric or seismic attribute volumes and the descriptor volumes to form an analysis dataset; and
(d) iteratively training a machine learning (ML) model based on the analysis dataset, and weighting and evaluating the one or more geometric or seismic attribute volumes and the descriptor volumes resulting in a probability prediction value for each coordinate in the subsurface area.

2. The method of claim 1, further comprising:
predicting the relative confidence in a second set of the one or more seismic interpretation objects by providing a processed second set of the one or more seismic interpretation objects and a second set of the one or more geometric or seismic attribute volumes and the descriptor volumes to the trained ML model, and computing the relative confidence in the processed second set of the one or more seismic interpretation objects based on the probability prediction value from the trained ML model.

3. The method of claim 2, wherein the predicting comprises:
receiving and processing the second set of the one or more seismic interpretation objects and a second set of the one or more geometric or seismic attribute volumes and the descriptor volumes according to blocks (a)-(c);
providing the processed second set of the one or more seismic interpretation objects and the second set of the one or more geometric or seismic attribute volumes and the descriptor volumes to the trained ML model; and
computing the relative confidence in the second set of the one or more seismic interpretation objects based on the probability prediction value from the trained ML model.

4. The method of claim 1, wherein the one or more geometric or seismic attribute volumes and the descriptor volumes comprises:
coordinates including X, Y, and depth, edges, surface stability, vector attributes, horizon and fault prediction, seismic amplitude, surface attributes, seismic signature, horizon discontinuities, fault surfaces dominant frequency, reflectional intensity, and/or gradient magnitude.

5. The method of claim 1, wherein the processing comprises:
labeling the one or more seismic interpretation objects and the one or more geometric or seismic attribute volumes and the descriptor volumes based on characteristics of the one or more seismic interpretation objects and the one or more geometric or seismic attribute volumes and the descriptor volumes, wherein the characteristics include data quality, data geographic location, and proximity to a seismic feature.

6. The method of claim 5, wherein the processing comprises:
removing nulls and duplicates from the labeled one or more seismic interpretation objects and the labeled one or more geometric or seismic attribute volumes and the descriptor volumes to produce cleaned data.

7. The method of claim 6, wherein the processing comprises:
scaling the cleaned data to produce scaled data; and
balancing the scaled data to produce balanced data.

8. The method of claim 7, wherein the processing comprises:
merging the balanced data to produce the analysis dataset.

9. The method of claim 8, wherein the analysis dataset comprises:
the labeled one or more seismic interpretation objects.

10. The method of claim 1, wherein the probability prediction value comprises:
a continuous representation of the relative confidence in the one or more seismic interpretation objects, the continuous representation being tested against a set of metrics to determine if the ML model is to be adjusted to improve model performance.

11. A computing system for computing a relative confidence of one or more seismic interpretation objects, the computing system comprising:
a hardware processor;
a non-volatile storage medium storing instructions that when executed by the hardware processor perform operations comprising:
(a) receiving the one or more seismic interpretation objects associated with a subsurface area;
(b) computing one or more geometric or seismic attribute volumes and descriptor volumes associated with the one or more seismic interpretation objects, wherein the one or more geometric or seismic attribute volumes and the descriptor volumes include:
coordinates including X, Y, and depth, edges, surface stability, vector attributes, horizon and fault prediction, seismic amplitude, surface attributes, seismic signature, horizon discontinuities, fault surfaces dominant frequency, reflectional intensity, and/or gradient magnitude;
(c) processing the one or more seismic interpretation objects and the one or more geometric or seismic attribute volumes and the descriptor volumes to form an analysis dataset; and
(d) iteratively training a machine learning (ML) model based on the analysis dataset, and weighting and evaluating the one or more geometric or seismic attribute volumes and the descriptor volumes resulting in a probability prediction value for each coordinate in the subsurface area.

12. The computing system of claim 11, wherein the operations further comprise:
predicting the relative confidence in a second set of the one or more seismic interpretation objects by providing a processed second set of the one or more seismic interpretation objects and a second set of the one or more geometric or seismic attribute volumes and the descriptor volumes to the trained ML model, and computing the relative confidence in the second set of the one or more seismic interpretation objects based on the probability prediction value from the trained ML model.

13. The computing system of claim 12, wherein the predicting comprises:
receiving and processing the second set of the one or more seismic interpretation objects and the second set of the one or more geometric or seismic attribute volumes and the descriptor volumes according to blocks (a)-(c);
providing the processed second set of the one or more seismic interpretation objects and the second set of the one or more geometric or seismic attribute volumes and the descriptor volumes to the trained ML model; and
computing the relative confidence in the second set of the one or more seismic interpretation objects based on the probability prediction value from the trained ML model.

14. The computing system of claim 11, wherein the processing comprises:
labeling the one or more seismic interpretation objects and the one or more geometric or seismic attribute volumes and the descriptor volumes based on characteristics of the one or more seismic interpretation objects and the one or more geometric or seismic attribute volumes and the descriptor volumes, wherein the characteristics include data quality, data geographic location, and proximity to a seismic feature; and
removing nulls and duplicates from the labeled one or more seismic interpretation objects and the labeled one or more geometric or seismic attribute volumes and the descriptor volumes to produce cleaned data.

15. The computing system of claim 14, wherein the processing comprises:
scaling the cleaned data to produce scaled data.

16. The computing system of claim 15, wherein the processing comprises:
balancing the scaled data to produce balanced data.

17. The computing system of claim 16, wherein the processing comprises:
merging the balanced data to produce the analysis dataset.

18. The computing system of claim 17, wherein the analysis dataset comprises:
the labeled one or more seismic interpretation objects.

19. The computing system of claim 11, wherein the probability prediction value comprises:
a continuous representation of the relative confidence in the one or more seismic interpretation objects, the continuous representation being tested against a set of metrics to determine if the ML model is to be adjusted to improve model performance.

20. A non-transitory computer-readable medium storing instructions for computing a relative confidence of one or more seismic interpretation objects that, when executed by one or more processors of a computing system, cause the computing system to perform operations, the operations comprising:
(a) receiving the one or more seismic interpretation objects associated with a subsurface area;
(b) computing one or more geometric or seismic attribute volumes and descriptor volumes associated with the one or more seismic interpretation objects, wherein the one or more geometric or seismic attribute volumes and the descriptor volumes include:
coordinates including X, Y, and depth, edges, surface stability, vector attributes, horizon and fault prediction, seismic amplitude, surface attributes, seismic signature, horizon discontinuities, fault surfaces dominant frequency, reflectional intensity, and gradient magnitude;
(c) processing the one or more seismic interpretation objects and the one or more geometric or seismic attribute volumes and the descriptor volumes to form an analysis dataset, wherein the processing includes:
labeling the one or more seismic interpretation objects and the one or more geometric or seismic attribute volumes and the descriptor volumes based on characteristics of the one or more seismic interpretation objects and the one or more geometric or seismic attribute volumes and the descriptor volumes, wherein the characteristics include data quality, data geographic location, and proximity to a seismic feature;
removing nulls and duplicates from labeled the one or more seismic interpretation objects and the labeled one or more geometric or seismic attribute volumes and the descriptor volumes to produce cleaned data;
scaling the cleaned data to produce scaled data;
balancing the scaled data to produce balanced data; and
merging the balanced data to produce the analysis dataset, wherein the analysis dataset includes:
the labeled one or more seismic interpretation objects;
(d) iteratively training a machine learning (ML) model based on the analysis dataset, and weighting and evaluating the one or more geometric or seismic attribute volumes and the descriptor volumes resulting in a probability prediction value for each coordinate in the subsurface area, wherein the probability prediction value includes:
a continuous representation of the relative confidence in the one or more seismic interpretation objects, the continuous representation being tested against a set of metrics to determine if the ML model is to be adjusted to improve model performance;
(e) predicting the relative confidence in a second set of the one or more seismic interpretation objects by providing a processed second set of the one or more seismic interpretation objects and a second set of the one or more geometric or seismic attribute volumes and the descriptor volumes to the trained ML model, and computing the relative confidence in the processed second set of the one or more seismic interpretation objects based on the probability prediction value from the trained ML model wherein the predicting includes:
receiving and processing the second set of the one or more seismic interpretation objects and a second set of the one or more geometric or seismic attribute volumes and the descriptor volumes according to blocks (a)-(c);
providing the processed second set of the one or more seismic interpretation objects and the second set of the one or more geometric or seismic attribute volumes and the descriptor volumes to the trained ML model; and
computing the relative confidence in the second set of the one or more seismic interpretation objects based on the probability prediction value from the trained ML model; and
(f) updating a 3D subsurface framework based on the computed relative confidence to improve subsurface framework quality and field development decisions related to the 3D subsurface framework, displaying 3D subsurface framework, and performing a wellsite action.
